(19) United States
(12) Patent Application Publication
(10) Pub. No.: US 2026/0329188 A1
(43) Pub. Date: Oct. 22, 2026

(54) SUBSTRATE SUPPORT MEMBER, LITHOGRAPHY APPARATUS, AND ARTICLE MANUFACTURING METHOD

(71) Applicant: CANON KABUSHIKI KAISHA, Tokyo (JP)

(72) Inventors: KAZUNORI NAKAJIMA, Tokyo (JP); SHIGEO KOYA, Tochigi (JP); YUICHIRO MORIKUNI, Tochigi (JP); MIDAI SUZUKI, Tokyo (JP); YUICHIRO OGUCHI, Tokyo (JP)

(21) Appl. No.: 19/647,564

(22) Filed: Apr. 14, 2026

(30) Foreign Application Priority Data
Apr. 21, 2025 (JP) 2025-069894

(51) Int. Cl. G03F 7/00; H10P 72/76

(52) U.S. Cl. CPC G03F 7/707; H10P 72/7614

(57) ABSTRACT

A substrate support member that supports a substrate includes a base, a plurality of pins provided on an upper surface of the base and configured to support the substrate, and a plurality of partition walls configured to partition a space between the upper surface and the substrate supported by the pins. The partition walls are concentrically arranged, each of the partition walls is lower than the pins, the partition walls include a first partition wall, a second partition wall outside the first partition wall, and a third partition wall outside the second partition wall, and air flow resistance between a partition wall upper end face and the substrate supported by the pins is reduced from the first partition wall, the second partition wall, and the third partition wall, in such order.

### BACKGROUND

### Field of the Technology

The present disclosure relates to a substrate support member, a lithography apparatus, and an article manufacturing method.

### Description of the Related Art

In a lithography process for manufacturing a semiconductor element, a liquid crystal display element, or the like, an exposure apparatus transfers, via a projection optical system, a pattern formed on an original (mask or reticle) onto a substrate (wafer or glass plate) with a resist or the like applied thereon. Such an exposure apparatus includes a stage that can move while supporting a substrate. The stage holds the substrate by vacuum chucking or the like using a substrate chuck. A pin-chuck type substrate chuck is broadly used as the substrate chuck. In the outer peripheral portion of the upper surface of the pin-chuck type substrate chuck, an annular partition wall (which is called a bank portion or a rim portion) is provided, and a plurality of pin members are evenly arranged in a region inside the annular partition wall. When a substrate is mounted on the plurality of pin members and a decompressed space formed between the substrate and the annular partition wall is vacuum-exhausted, the substrate is held by the substrate chuck.

Warpage of a substrate can influence the chucking performance of the substrate. Japanese Patent Laid-Open No. 2007-273693 discusses that the second annular protrusion is provided inside the first annular protrusion to improve the substrate chucking capability. However, if air flow resistance due to the throttling effect on the second annular protrusion is made excessively large, an exhaust flow rate becomes insufficient, and a substrate that is significantly warped in a concave shape cannot be chucked.

To chuck a substrate with warpage, increasing the exhaust flow rate during chucking may lead to the increased apparatus size and complexity.

### SUMMARY

The present disclosure provides a technique advantageous for effectively chucking and holding a substrate with a low exhaust flow rate.

An aspect of the present disclosure provides a substrate support member for supporting a substrate, the substrate support member including a base; a plurality of pins provided on an upper surface of the base, configured to support the substrate; and a plurality of partition walls configured to partition a space between the upper surface and the substrate supported by the plurality of pins. The plurality of partition walls are concentrically arranged. Each of partition wall of the plurality of partition walls is lower than the plurality of pins. The plurality of partition walls include a first partition wall, a second partition wall outside the first partition wall, and a third partition wall outside the second partition wall. Air flow resistance between a partition wall upper end face and the substrate supported by the plurality of pins is reduced from the first partition wall, the second partition wall, and the third partition wall, in this order.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the present disclosure, illustrate embodiments of the present disclosure, and together with the description, serve to explain the principles of the embodiments.

FIG. 1 is a schematic view showing the configuration of a lithography apparatus;

FIG. 2 is a sectional view showing an example of the configuration of a chuck;

FIG. 3 is a top view showing an example of the configuration of the chuck;

FIG. 4 is a top view showing an example of the configuration of the chuck;

FIG. 5 is a top view showing an example of the configuration of the chuck;

FIG. 6 is a top view showing an example of the configuration of the chuck; and

FIG. 7 is a sectional view showing an example of the configuration of a chuck.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required all such features, and multiple such features may be combined as appropriate. In the attached drawings, the same reference numerals are given to the same or similar configurations, and redundant description thereof is incorporated by reference without repetition thereof, for conciseness.

A substrate support member according to the present disclosure can be applied to lithography apparatuses for forming a pattern on a substrate, such as an exposure apparatus and an imprint apparatus, but may be applied to other substrate processing apparatuses such as a processing apparatus and an inspection apparatus. An example in which the substrate support member according to the present disclosure is applied to a lithography apparatus will be described below.

### First Embodiment

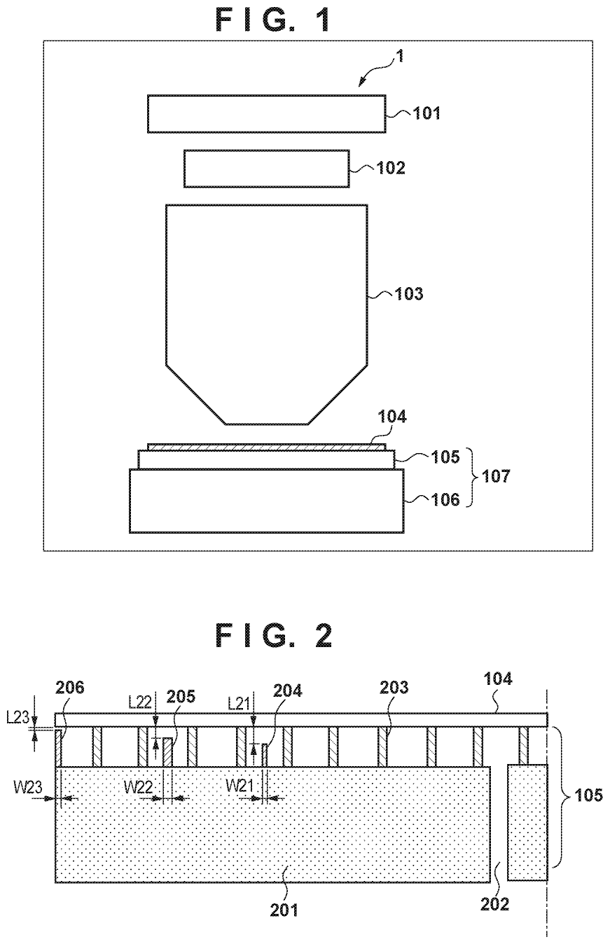

FIG. 1 is a schematic view showing the configuration of a lithography apparatus 1 according to an embodiment. The lithography apparatus 1 is an apparatus that forms (transfers) a pattern onto a substrate. In this embodiment, the lithography apparatus 1 is embodied as an exposure apparatus that forms a pattern on a substrate by exposing the substrate via a projection optical system. However, the lithography apparatus 1 is not limited to the exposure apparatus. For example, the lithography apparatus 1 may be a drawing apparatus that forms a pattern on a substrate by drawing the pattern on the substrate with a charged particle beam (an electron beam, ion beam, or the like) via a charged particle optical system. In addition, the lithography apparatus 1 may be an imprint apparatus that forms a pattern on a substrate by shaping an imprint material on the substrate using a mold.

As shown in FIG. 1, the lithography apparatus 1 includes an illumination optical system 101, an original stage that holds an original 102, a projection optical system 103, and a substrate stage 107 that holds a substrate 104. The substrate 104 can be a wafer or a glass plate, without limitation thereto.

In the lithography apparatus 1, light from a light source illuminates the original 102 held by the original stage via the illumination optical system 101. The light having passed through the original 102 is applied to the substrate 104 via the projection optical system 103 (that is, an image of the pattern of the original 102 is formed on the substrate 104).

The substrate stage 107 can include a chuck 105 serving as a substrate support member that can move while holding the substrate 104, and a stage main body 106 that supports the chuck 105. The stage main body 106 can include a driving mechanism for moving the substrate 104 in, for example, six axial directions.

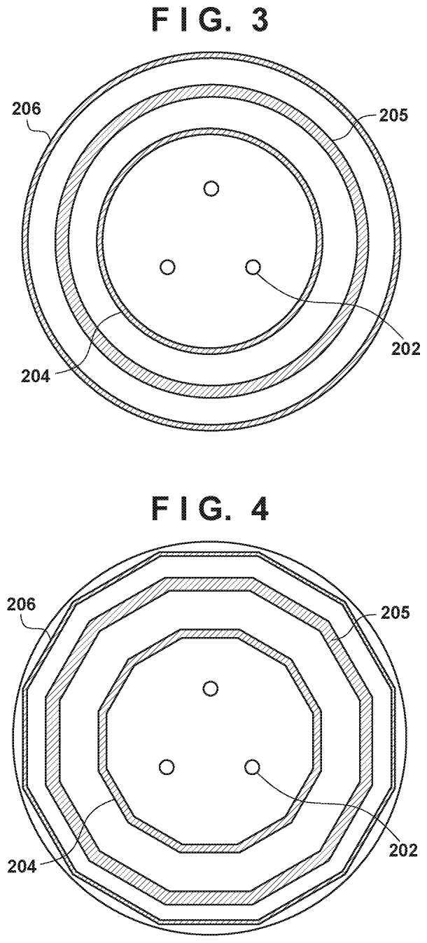

FIGS. 2 and 3 are a sectional view and a top view of the chuck 105 in this embodiment, respectively. A base 201 of the chuck 105 is made of a material having excellent thermal conductivity, for example, silicon carbide (SiC) ceramics. One or more substrate vacuum holes 202, which are through holes extending vertically through the base 201, are formed in the base 201. The one or more substrate vacuum holes 202 are connected to a vacuum source. Chuck vacuum holes for chucking the chuck 105 to the stage main body 106 are formed in the stage main body 106 and connected to a vacuum source.

To convey the substrate 104 onto the chuck 105 or collect the substrate 104 from the chuck 105, lift pins are used to transfer the substrate 104 (pins that chuck the substrate 104 and move vertically relative to the stage main body 106). Therefore, as through holes extending through the base 201, lift pin holes having a larger diameter than the lift pins are also formed in the base 201.

The chuck 105 includes a plurality of pins 203 extending upward from the upper surface of the base 201. The upper surfaces of the plurality of pins 203 constitute a substrate support surface (mounting surface) that contacts the back surface of the substrate 104 and supports the substrate 104. The chuck 105 also includes a plurality of partition walls for partitioning a space between the upper surface of the base 201 and the substrate 104 supported by the plurality of pins 203. The plurality of partition walls are provided to make the space between the substrate 104 and the base 201 a decompressed space. In this embodiment, the plurality of partition walls are concentrically arranged.

In this embodiment, the plurality of partition walls can include a first partition wall 204, a second partition wall 205 outside the first partition wall 204, and a third partition wall 206 outside the second partition wall 205. The third partition wall 206 is installed in the outer peripheral portion of the base 201. Therefore, the third partition wall 206 may also be called an outer peripheral partition wall. Since the first partition wall 204 and the second partition wall 205 are installed inside the third partition wall 206, these may be called intermediate partition walls. In this embodiment, there are two intermediate partition walls including the first partition wall 204 and the second partition wall 205, but there may be three or more intermediate partition walls. An example where there are three intermediate partition walls will be described later as the second embodiment. The centers of the partition walls can be at the same position.

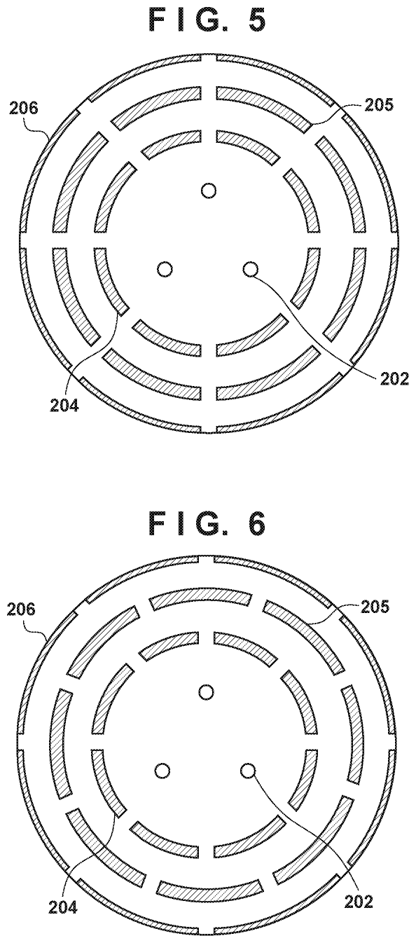

Each of the first partition wall 204, the second partition wall 205, and the third partition wall 206 may be formed in an annular shape in a planar view (a projection from above), as shown in FIG. 3. Alternatively, it may be formed in a polygonal shape in a planar view, as shown in FIG. 4. As shown in FIGS. 5 and 6, a plurality of slits arranged at equal intervals may be formed in each of the first partition wall 204, the second partition wall 205, and the third partition wall 206.

By such arrangement of the substrate support surface, the plurality of pins 203 can hold the substrate 104 while keeping high flatness during vacuum-chucking of the substrate 104. The plurality of pins 203 are arranged at approximately equal intervals. For example, the plurality of pins 203 may be arranged at a pitch of 3.0 mm or less. Note that in FIG. 2, each of the plurality of pins 203 is shown in a simple cylindrical shape, but it may have, for example, a two-stage pin shape with a thin upper stage and a thick lower stage.

The third partition wall 206 is formed slightly lower than the plurality of pins 203, so that a certain clearance is provided between the back surface of the substrate 104 and the upper end face of the third partition wall 206. The position of the third partition wall 206 in the horizontal direction may be positioned close to the outer periphery (end portion) of the substrate 104. Note that in FIG. 2, the outer diameter of the third partition wall 206 matches the outer diameter of the substrate 104, but it does not necessarily match the outer diameter of the substrate 104. The third partition wall 206 may be arranged slightly (for example, several mm) inside the outer periphery of the substrate 104.

The positions and number of the substrate vacuum holes 202 are not particularly limited. The substrate vacuum holes 202 may be arranged in any number, as long as one or more substrate vacuum holes 202 are arranged inside the third partition wall 206. In an example, one or more substrate vacuum holes 202 are arranged inside the first partition wall 204. One or more lift pin holes are arranged inside the third partition wall 206.

Similar to the third partition wall 206, the first partition wall 204 and the second partition wall 205 are formed slightly lower than the plurality of pins 203, and do not contact the substrate 104.

The relationship among air flow resistances formed by the spaces between the substrate 104 and the first partition wall 204, the second partition wall 205, and the third partition wall 206, respectively, will be described. In this embodiment, air flow resistance between the partition wall upper end face and the substrate 104 supported by the plurality of pins 203 is reduced from the first partition wall 204, the second partition wall 205, and the third partition wall 206, in such order.

As shown in FIG. 2, the height difference between the plurality of pins 203 and the first partition wall 204 is L21. L21 corresponds to a clearance between the back surface of the substrate 104 and the upper end face (partition wall upper end face) of the first partition wall 204.

The height difference between the plurality of pins 203 and the second partition wall 205 is L22. L22 corresponds to a clearance between the back surface of the substrate 104 and the upper end face of the second partition wall 205.

The height difference between the plurality of pins 203 and the third partition wall 206 is L23. L23 corresponds to a clearance between the back surface of the substrate 104 and the upper end face of the third partition wall 206.

In a case where the heights of the first partition wall 204, the second partition wall 205, and the third partition wall 206 (the clearances from the substrate 104) are set without considering the widths of the first partition wall 204, the second partition wall 205, and the third partition wall 206. Here, for example, the first partition wall 204, the second partition wall 205, and the third partition wall 206 have the same width. In this case, in this embodiment, the first partition wall 204 is set lower than the second partition wall 205. That is, L21>L22 is set. This can make air flow resistance between the first partition wall 204 and the substrate 104 supported by the plurality of pins 203 smaller than air flow resistance between the second partition wall 205 and the substrate 104. In this embodiment, the second partition wall 205 is set lower than the third partition wall 206. That is, L22>L23 is set. This can make air flow resistance between the second partition wall 205 and the substrate 104 supported by the plurality of pins 203 smaller than air flow resistance between the third partition wall 206 and the substrate 104.

Next, the widths of the first partition wall 204, the second partition wall 205, and the third partition wall 206 are considered. The width of the first partition wall 204 is W21, the width of the second partition wall 205 is W22, and the width of the third partition wall 206 is W23. In an example, each of W21, W22, and W23 can be 3.0 mm or less.

In this case, the relationship concerning the width and the clearance (the height difference between the partition wall and the plurality of pins 203) between the first partition wall 204 and the second partition wall 205 can be set, for example, according to Equation (1):

W21×L21⁻³<W22×L22⁻³ (1)

The relationship concerning the width and the clearance (the height difference between the partition wall and the plurality of pins 203) between the second partition wall 205 and the third partition wall 206 can be set, for example, according to Equation (2):

W22×L22⁻³<W23×L23⁻³ (2)

Air flow resistance immediately above each intermediate partition wall is similar to the flow resistance between parallel flat plates, and is proportional to the partition wall width and the clearance to the power of minus three.

Alternatively, the relationship concerning the width and the clearance (the height difference between the partition wall and the plurality of pins 203) between the first partition wall 204 and the second partition wall 205 may be set according to Equation (3):

W21×L21⁻²<W22×L22⁻² (3)

The relationship concerning the width and the clearance (the height difference between the partition wall and the plurality of pins 203) between the second partition wall 205 and the third partition wall 206 may be set, for example, according to Equation (4):

W22×L22⁻²<W23×L23⁻² (4)

Air flow resistance above each intermediate partition wall is proportional to the partition wall width and the clearance to the power of minus two.

Alternatively, the relationship concerning the width and the clearance (the height difference between the partition wall and the plurality of pins 203) between the first partition wall 204 and the second partition wall 205 may be set, for example, according to Equation (5):

W21×L21⁻¹<W22×L22⁻¹ (5)

The relationship concerning the width and the clearance (the height difference between the partition wall and the plurality of pins 203) between the second partition wall 205 and the third partition wall 206 may be set, for example, accordingly to Equation (6):

W22×L22⁻¹<W23×L23⁻¹ (6)

Air flow resistance above each intermediate partition wall is similar to the flow resistance in a pipe, and is proportional to the partition wall width and the clearance to the power of minus one.

According to this embodiment, air flow resistances are generated above the first partition wall 204 and the second partition wall 205. Thus, chucking may be reliably performed of a concavely warped substrate from the central portion to the regions above the first partition wall 204 and the second partition wall 205, thereby flattening the substrate. When the substrate is flattened up to the regions above the first partition wall 204 and the second partition wall 205, the residual warpage amount of the substrate decreases. Thus, the concavely warped substrate can be easily chucked even in the region outside the second partition wall 205. By setting a smallest air flow resistance immediately above the first partition wall 204, which is the innermost intermediate partition wall, the throttling effect is made small in the region where the substrate warpage amount is small, thereby reducing the loss of the exhaust flow rate. Accordingly, the exhaust flow rate in the region outside the first partition wall 204, where the warpage amount of the substrate is larger, can be ensured. Hence, a substrate support member is provided that is capable of performing a chucking process on a warped substrate with a low exhaust flow rate.

### Second Embodiment

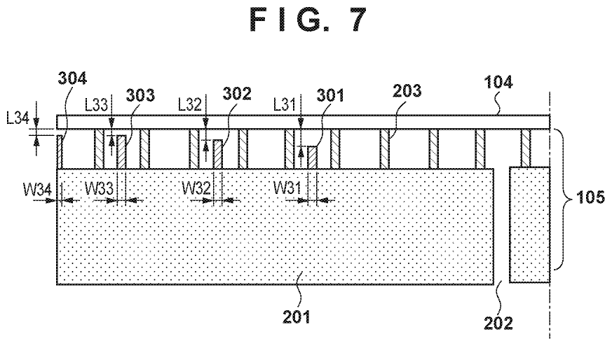

The second embodiment according to the present disclosure will be described below. Matters not specifically described in the second embodiment are incorporated by reference from the first embodiment. FIG. 7 shows a sectional view of a chuck 105 according to the second embodiment. The chuck 105 according to the second embodiment is obtained by changing the configurations of a plurality of intermediate partition walls and an outer peripheral partition wall from the configurations according to the first embodiment. The chuck 105 includes a plurality of partition walls for partitioning a space between the upper surface of a base 201 and a substrate 104 supported by a plurality of pins 203. In this embodiment, the plurality of partition walls are concentrically arranged. The plurality of partition walls can include a first partition wall 301, a second partition wall 302 outside the first partition wall 301, a third partition wall 303 outside the second partition wall 302, and a fourth partition wall 304 outside the third partition wall 303. The fourth partition wall 304 is installed in the outer peripheral portion of the base 201. Accordingly, the fourth partition wall 304 may also be called an outer peripheral partition wall. The first partition wall 301, the second partition wall 302, and the third partition wall 303 are provided inside the fourth partition wall 304. Accordingly, the first partition wall 301, the second partition wall 302, and the third partition wall 303 may also be referred to as intermediate partition walls. The centers of the partition walls can be at the same position.

The fourth partition wall 304 is formed slightly lower than the plurality of pins 203. The first partition wall 301, the second partition wall 302, and the third partition wall 303 are formed slightly lower than the plurality of pins 203, and do not contact the substrate 104. As shown in FIG. 7, the height difference between the plurality of pins 203 and the first partition wall 301 is L31, and the height difference between the plurality of pins 203 and the second partition wall 302 is L32. The height difference between the plurality of pins 203 and the third partition wall 303 is L33. The height difference between the plurality of pins 203 and the fourth partition wall 304 is L34. the width of the first partition wall 301 is W31, the width of the second partition wall 302 is W32, the width of the third partition wall 303 is W33, and the width of the fourth partition wall 304 is W34. In this case, the relationship concerning the width and the clearance among the partition walls is set, for example, according to Equation (7):

W31×L31⁻³<W32×L32⁻³<W33×L33⁻³<W34×L34⁻³ (7)

Alternatively, the relationship concerning the width and the clearance among the partition walls may be set, for example, according to Equation (8):

W31×L31⁻²<W32×L32⁻²<W33×L33⁻²<W34×L34⁻² (8)

Alternatively, the relationship concerning the width and the clearance among the partition walls may be set, for example, according to Equation (9):

W31×L31⁻¹<W32×L32⁻¹<W33×L33⁻¹<W34×L34⁻¹ (9)

With this, the minimum throttling effect is provided in the space above each partition wall. Accordingly, a substrate support member is provide that can perform a chucking process on a concavely warped substrate with a low exhaust flow rate.

### Embodiment of Article Manufacturing Method

An article manufacturing method according to the present disclosure is suitable to, for example, manufacture an article such as a flat panel display (FPD), a semiconductor device, a sensor, or an optical element. The article manufacturing method according to this embodiment includes a step (formation step) of transferring (forming) the pattern of an original onto a substrate using the above-described lithography apparatus (exposure apparatus, imprint apparatus, drawing apparatus, or the like), and a step (processing step) of processing the substrate with the pattern transferred (formed) thereto in the above step. The article manufacturing method also includes other known steps (oxidation, deposition, vapor deposition, doping, planarization, etching, resist peeling, dicing, bonding, and packaging). The article manufacturing method according to this embodiment is advantageous in at least one of the performance, quality, productivity, and production cost of an article as compared to a conventional method.

According to the present disclosure, a technique advantageous for effectively chucking and holding a substrate with a low exhaust flow rate can be provided.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-069894, filed Apr. 21, 2025 which is hereby incorporated by reference herein in its entirety.

What is claimed is:

1. A substrate support member for supporting a substrate, the substrate support member comprising:
a base;
a plurality of pins provided on an upper surface of the base, configured to support the substrate; and
a plurality of partition walls configured to partition a space between the upper surface and the substrate supported by the plurality of pins,
wherein
the plurality of partition walls are concentrically arranged,
each partition wall of the plurality of partition walls is lower than the plurality of pins,
the plurality of partition walls include a first partition wall, a second partition wall outside the first partition wall, and a third partition wall outside the second partition wall, and
air flow resistance between a partition wall upper end face and the substrate supported by the plurality of pins is reduced from the first partition wall, the second partition wall, and the third partition wall, in such order.

2. The substrate support member according to claim 1, wherein a height of a partition wall upper end face increases from the first partition, to the second partition, to the third partition, in such order.

3. The substrate support member according to claim 1, wherein dimensions of the first partition wall and the second partition wall satisfy:
W21×L21⁻³<W22×L22⁻³,
wherein L21 is a height difference between the plurality of pins and the first partition wall,
L22 is a height difference between the plurality of pins and the second partition wall,
W21 is a width of the first partition wall, and
W22 is a width of the second partition wall.

4. The substrate support member according to claim 3, wherein dimensions of the second partition wall and the third partition wall satisfy:
W22×L22⁻³<W23×L23⁻³,
wherein L23 is a height difference between the plurality of pins and the third partition wall, and
W23 is a width of the third partition wall.

5. The substrate support member according to claim 1, wherein dimensions of the first partition wall and the second partition wall satisfy:
W21×L21⁻²<W22×L22⁻²,
wherein L21 is a height difference between the plurality of pins and the first partition wall,
L22 is a height difference between the plurality of pins and the second partition wall,
W21 is a width of the first partition wall, and
W22 is a width of the second partition wall.

6. The substrate support member according to claim 5, wherein dimensions of the second partition wall and the third partition wall satisfy:
W22×L22⁻²<W23×L23⁻²,
wherein L23 is a height difference between the plurality of pins and the third partition wall, and
W23 is a width of the third partition wall.

7. The substrate support member according to claim 1, wherein dimensions of the first partition wall and the second partition wall satisfy:
W21×L21⁻¹<W22×L22⁻¹,
wherein L21 is a height difference between the plurality of pins and the first partition wall,
L22 is a height difference between the plurality of pins and the second partition wall,
W21 is a width of the first partition wall, and
W22 is a width of the second partition wall.

8. The substrate support member according to claim 7, wherein dimensions of the second partition wall and the third partition wall satisfy:
W22×L22⁻¹<W23×L23⁻¹,
wherein L23 is a height difference between the plurality of pins and the third partition wall, and
W23 is a width of the third partition wall.

9. The substrate support member according to claim 1, wherein a width of each of the first partition wall, the second partition wall, and the third partition wall is less than 3.0 mm.

10. The substrate support member according to claim 1, wherein each of the first partition wall, the second partition wall, and the third partition wall has an annular shape in a planar view.

11. The substrate support member according to claim 1, wherein each of the first partition wall, the second partition wall, and the third partition wall has a polygonal shape in a planar view.

12. A lithography apparatus that forms a pattern of an original on a substrate, comprising:
the substrate support member according to claim 1,
wherein the substrate support member is configured to support the substrate.

13. An article manufacturing method comprising:
forming a pattern on a substrate using a lithography apparatus according to claim 12; and
processing the substrate with the pattern formed thereon,
wherein an article is manufactured from the substrate processed in the processing.
